(19) United States
(12) Patent Application Publication
(10) Pub. No.: US 2025/0108463 A1
(43) Pub. Date: Apr. 3, 2025

(54) BONDING MATERIAL AND BONDING STRUCTURE

(71) Applicant: Panasonic Intellectual Property Management Co., Ltd., Osaka (JP)

(72) Inventors: KIYOHIRO HINE, Osaka (JP); YUMI TAKAO, Hyogo (JP); HIROHISA HINO, Osaka (JP); SHINJI ISHITANI, Hyogo (JP); AKIO FURUSAWA, Osaka (JP)

(21) Appl. No.: 18/978,382

(22) Filed: Dec. 12, 2024

Related U.S. Application Data
(63) Continuation of application No. PCT/JP2023/018864, filed on May 22, 2023.

(30) Foreign Application Priority Data
Jun. 23, 2022 (JP) 2022-101096

(51) Int. Cl. B23K 35/02; B23K 35/26; B23K 35/36; B23K 101/42; C22C 13/02; H05K 1/18

(52) U.S. Cl. CPC B23K 35/025; B23K 35/262; B23K 35/3618; C22C 13/02; H05K 1/181; B23K 2101/42

(57) ABSTRACT

A bonding material includes a solder alloy having a median diameter D50 of 100 nm to 2000 nm, made from Sn, Bi, In, and other unavoidable components, and having a melting point of less than or equal to 100° C., metal nanoparticles that are Cu nanoparticles having a median diameter D50 of 50 nm to 500 nm, and a flux, wherein the metal nanoparticles include a protective film on a surface of the metal nanoparticles, the protective film separating at a temperature higher than a melting point of the solder alloy and lower than 100° C., and a weight ratio between the solder alloy and the metal nanoparticles is a ratio at which all Sn and In contained in the solder alloy become intermetallic compounds with the metal nanoparticles in an equilibrium state diagram.

### TECHNICAL FIELD

The present disclosure relates to a bonding material and a bonding structure for bonding two members with a metal material, for use in the field of printable electronics or the like.

### BACKGROUND ART

In devices used in the field of printable electronics or the like, there is a device having a bonding structure in which two members of a substrate having an electric circuit using a resin having a film shape as a base material and an electronic component are bonded for the purpose of imparting flexibility.

Various resins such as polyethylene terephthalate (PET), polyamide, and polyimide are used as a resin having a film shape intended to have flexibility, and use of a PET film is desired in terms of price.

Since the PET film has a low glass transition temperature, there is a problem that the PET film cannot withstand the soldering temperature when electronic components are bonded onto the substrate with a typical lead-free solder (for example, Sn-3.5Ag-0.5Cu, melting point: 219° C.).

For this reason, when a PET film base material is used, it is necessary to perform bonding using a silver paste obtained by adding particulate silver to a thermosetting resin or a lead-free solder having a low melting point as a bonding material for an electronic component.

However, in the case of a silver paste, the silver paste is bonded through adhesion by curing of a thermosetting resin, and it is necessary to use a silver paste having a low curing temperature when the silver paste is used for a PET film base material having low heat resistance. The melting point is low also in the case of bonding by using lead-free solder having a low melting point, and remelting occurs when the temperature rises to the melting point or higher after bonding. Therefore, in any case, there is a problem that heat resistance after bonding is low.

For this reason, there is a demand for a bonding material and a bonding structure having characteristics that a temperature at the time of bonding is low and heat resistance after bonding is excellent.

As one solution to such a problem, there has been proposed a bonding material including silver nanoparticles that are nano-sized silver and eutectic low melting point alloy particles, wherein the silver nanoparticles are annealed by heating, and the melted eutectic low melting point alloy particles flow into spaces between the annealed silver nanoparticles to fill the space, and they are solidified to form a bond (see PTL 1, for example).

### CITATION LIST

### Patent Literature

PTL 1: Unexamined Japanese Patent Publication No. 2018-137213

### SUMMARY OF THE INVENTION

A bonding material according to one aspect of the present disclosure includes a solder alloy having a median diameter D50 of 100 nm to 2000 nm, made from Sn, Bi, In, and other unavoidable components, and having a melting point of less than or equal to 100° C., metal nanoparticles that are Cu nanoparticles having a median diameter D50 of 50 nm to 500 nm, and a flux component, wherein the metal nanoparticles include a protective film on a surface of the metal nanoparticles, the protective film separating at a temperature higher than a melting point of the solder alloy and lower than 100° C., and a weight ratio between the solder alloy and the metal nanoparticles is a ratio at which all Sn and In contained in the solder alloy become intermetallic compounds with the metal nanoparticles in an equilibrium state diagram.

A bonding structure according to one aspect of the present disclosure includes an electronic component including a first electrode, a circuit board including a second electrode, and a bonding layer between the first electrode and the second electrode, wherein the first electrode and the second electrode are bonded by the bonding layer, the bonding layer is connected between the first electrode and the second electrode by an intermetallic compound made from two or more elements of Cu, Sn, and In, and a Bi- containing portion is included in an island shape in a base of the intermetallic compound.

### BRIEF DESCRIPTION OF THE DRAWINGS

FIG. 1 is a schematic view illustrating a configuration of a bonding material according to a first exemplary embodiment.

FIG. 2 is a schematic view illustrating a configuration of a bonding structure according to the present first exemplary embodiment.

FIG. 3 is a diagram illustrating Table 1 showing components, particle sizes, and weight ratios contained in bonding materials in Examples 1-1 to 1-8 and Comparative Examples 1-1 to 1-12, and evaluation results.

FIG. 4 is a diagram illustrating Table 2 showing conditions of bonding materials and evaluation results in Examples 2-1 to 2-10 and Comparative Examples 2-1 to 2-6.

### DESCRIPTION OF EMBODIMENT

In the bonding material described in PTL 1, the eutectic low melting point alloy remains even after bonding with short-time heating, and thus there is a problem that remelting occurs when the temperature rises to the melting point or higher after bonding. In addition, it is necessary to perform annealing for a long time for sintering the silver nanoparticles to secure heat resistance, and thermal damage to the resin substrate increases, which causes a problem in a resin substrate having low heat resistance.

The present disclosure solves the conventional problems, and an object of the present disclosure is to provide a bonding material and a bonding structure capable of exhibiting high heat resistance with heating at a low temperature for a short time.

A bonding material according to one embodiment includes a solder alloy having a median diameter D50 of 100 nm to 2000 nm, made from Sn, Bi, In, and other unavoidable components, and having a melting point of less than or equal to 100° C., metal nanoparticles that are Cu nanoparticles having a median diameter D50 of 50 nm to 500 nm, and a flux, wherein the metal nanoparticles include a protective film on a surface of the metal nanoparticles, the protective film separating at a temperature higher than a melting point of the solder alloy and lower than 100° C., and a weight ratio between the solder alloy and the metal nanoparticles is a ratio at which all Sn and In contained in the solder alloy become intermetallic compounds with the metal nanoparticles in an equilibrium state diagram.

In a bonding material according to a second embodiment, in the first embodiment, a composition of the solder alloy may be Sn-55 wt. % Bi-20 wt. % In.

In a bonding material according to a third embodiment, in the first or second embodiment, a weight ratio of the metal nanoparticles to a total weight of the solder alloy and the metal nanoparticles may be 30 wt. % to 50 wt. %.

In a bonding material according to a fourth embodiment, in the first or second embodiment, a weight ratio of the metal nanoparticles to a total weight of the solder alloy and the metal nanoparticles may be 37.5 wt. % to 50 wt. %.

In a bonding material according to a fifth embodiment, in the first or second embodiment, a weight ratio of the metal nanoparticles to a total weight of the solder alloy and the metal nanoparticles may be 40 wt. % to 50 wt. %.

In a bonding material according to a sixth embodiment, in any one of the first to fifth embodiments, the protective film may be a linear carboxylic acid having 4 to 8 carbon atoms.

A bonding framework body according to a seventh embodiment includes an electronic component including a first electrode, a circuit board including a second electrode, and a bonding layer between the first electrode and the second electrode, wherein the first electrode and the second electrode are bonded by the bonding layer, the bonding layer is connected between the first electrode and the second electrode by an intermetallic compound made from two or more elements of Cu, Sn, and In, and a Bi-containing portion is included in an island shape in a base of the intermetallic compound.

According to the bonding material according to the present disclosure, it is possible to provide a bonding material and a bonding structure capable of quickly forming an intermetallic compound having a high melting point with metal nanoparticles after a solder alloy is melted and exhibiting high heat resistance when heated at a low temperature for a short time.

Hereinafter, a bonding material and a bonding structure according to one exemplary embodiment of the present disclosure will be described in detail with reference to the accompanying drawings.

### First Exemplary Embodiment

### <Bonding Material>

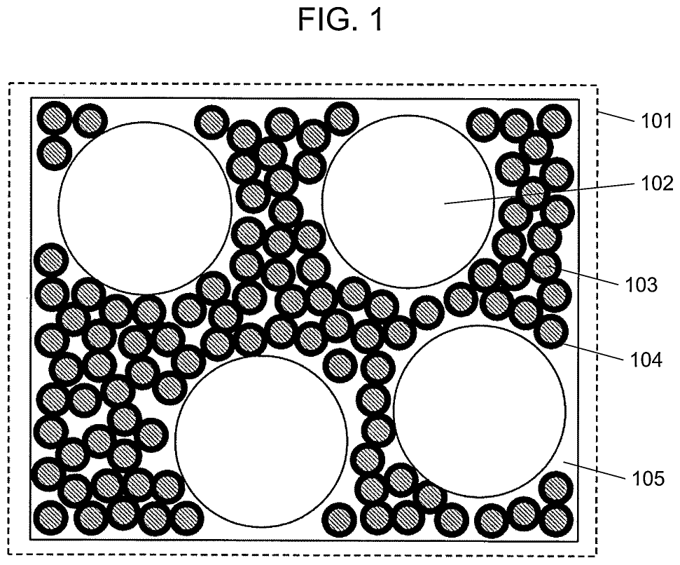

FIG. 1 is a schematic view illustrating a configuration of a bonding material according to a first exemplary embodiment.

Bonding material 101 according to the present first exemplary embodiment contains solder alloy 102, metal nanoparticles 103, and flux 105. Solder alloy 102 has a median diameter D50 of 100 nm to 2000 nm, is made from Sn, Bi, In, and other unavoidable components, and has a melting point of less than or equal to 100° C. The metal nanoparticles 103 are Cu nanoparticles having a median diameter D50 of 50 nm to 500 nm. Metal nanoparticles 103 have protective film 104 on their surfaces, and protective film 104 separates at a temperature higher than the melting point of solder alloy 102 and lower than 100° C. The weight ratio between solder alloy 102 and metal nanoparticles 103 is a ratio at which all Sn and In contained in the solder alloy become intermetallic compounds with metal nanoparticles 103 in an equilibrium state diagram.

As a result, remelting does not occur at a temperature of less than or equal to 100° C. in a bonding portion bonded using the bonding material. Thus, high heat resistance can be exhibited in which the bonding material does not melt even when the operating temperature of the device after bonding is more than or equal to 100° C.

### <Bonding Structure>

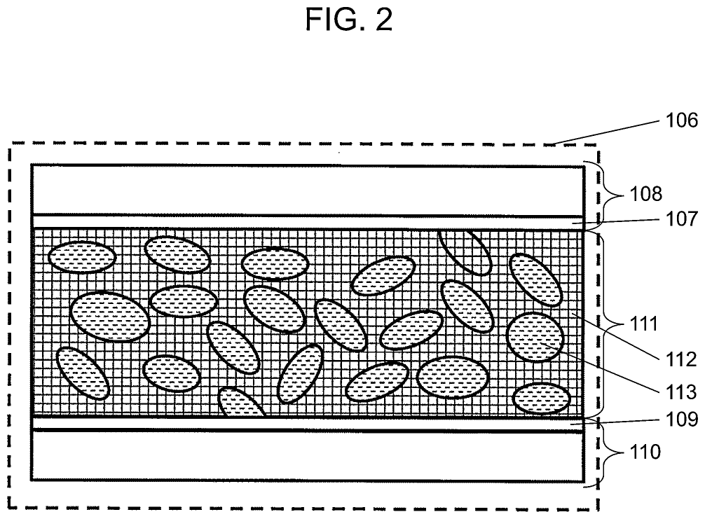

FIG. 2 is a schematic view illustrating a configuration of a bonding structure according to the present first exemplary embodiment.

Bonding structure 106 bonded with bonding material 101 according to the present first exemplary embodiment includes electronic component 108 having first electrode 107, circuit board 110 having second electrode 109, and bonding layer 111 between the first electrode and the second electrode. First electrode 107 and second electrode 109 are bonded by bonding layer 111. Bonding layer 111 is connected (blocked) between first electrode 107 and second electrode 109 by intermetallic compound 112 made from two or more elements of Cu, Sn, and In, and has island-like Bi-containing portion 113 in a base of the intermetallic compound made from two or more elements of Cu, Sn, and In. Although Bi-containing portion 113 contains a few other components of less than or equal to the solid solubility limit, it is substantially made only from Bi.

Here, the state of being connected (closed) refers to a state in which first electrode 107 and second electrode 109 are connected by an intermetallic compound and they are joined. The term “island-like” refers to a state in which no Bi-containing portion 113 is connected across first electrode 107 and second electrode 109, but all Bi-containing portions 113 are interspersed between the intermetallic compounds.

As a result, remelting does not occur even when the temperature of bonding structure 106 rises to the melting point of bonding material 101 or higher during the operation of the device having bonding structure 106, because bonding layer 111 does not contain a melting component. Thus, high heat resistance equal to or more than the bonding temperature can be exhibited.

Hereinafter, each member constituting the bonding material and the bonding structure will be described.

### <Solder Alloy>

Solder alloy 102 becomes a liquid phase component in the bonding process and reacts with metal nanoparticles 103 to form a high melting point intermetallic compound. Solder alloy 102 is made from Sn, Bi, In, and other unavoidable components, and has a melting point of less than or equal to 100° C. This enables bonding at a low temperature of 100° C. Further, since Sn and In can form an intermetallic compound having a high melting point with Cu of metal nanoparticles 103 described later, and Bi has a high melting point of 272° C., high heat resistance of not melting even at a temperature of more than or equal to 100° C. can be exhibited.

The intermetallic compound is an intermetallic compound made from two or more elements of Cu, Sn, and In.

Solder alloy 102 is particles having a median diameter D50 of 100 nm to 2000 nm. This makes it possible to form an intermetallic compound in a short time and to prevent generation of voids during the reaction between the liquid phase and the solid phase because the solder alloy has a large specific surface area and a particle size close to the particle size of metal nanoparticles 103.

### <Metal Nanoparticles>

Metal nanoparticles 103 react with Sn and In contained in solder alloy 102 melted in the bonding process to form an intermetallic compound. Metal nanoparticles 103 have a median diameter D50 of 50 nm to 500 nm. This makes it possible to form an intermetallic compound having a high melting point in a short time in the bonding process while suppressing aggregation in bonding material 101.

Metal nanoparticles 103 are Cu nanoparticles. This makes it possible to react with Sn and In contained in solder alloy 102 to form an intermetallic compound having a high melting point.

Metal nanoparticles 103 have protective film 104 described later on their surfaces. This makes it possible to suppress oxidation of their surfaces even in metal nanoparticles having a small particle size.

### <Protective Film>

Protective film 104 separates from the surfaces of metal nanoparticles 103 at a temperature more than or equal to the melting point of solder alloy 102 and less than or equal to 100° C. Having such protective film 104 makes it possible to suppress surface oxidation of metal nanoparticles 103 until solder alloy 102 melts. Then, protective film 104 separates after solder alloy 102 melts, and thus metal nanoparticles 103 are brought into contact with solder alloy 102 melted in a state where the amount of oxide film on the surfaces of metal nanoparticles 103 is very small. This causes the formation of the intermetallic compound between metal nanoparticles 103 and the solder alloy to rapidly proceed, which makes it possible to realize bonding excellent in heat resistance at a low temperature in a short time.

There is no problem as long as protective film 104 separates from the surfaces of metal nanoparticles 103 at a temperature more than or equal to the melting point of solder alloy 102 and less than or equal to 100° C. but in particular, the protective film is desirably a linear carboxylic acid having 4 to 8 carbon atoms. These components have a carboxyl group and separate from the surfaces of metal nanoparticles 103 at a temperature more than or equal to the melting point of solder alloy 102 and less than or equal to 100° C. This is considered to suppress oxidation of the surfaces of metal nanoparticles 103 and to cause rapid separation at 100° C., thereby contributing to removal of surface oxides of solder alloy 102 as an activator component. Thus, it is possible to realize bonding excellent in heat resistance at a lower temperature in a shorter time.

### <Flux>

Flux 105 is included to exhibit paste characteristics for material supply such as removal of the oxide film present on the surface of solder alloy 102, suppression of re-oxidation of metal nanoparticles 103, and application in the bonding process. Flux 105 facilitates the melting of solder alloy 102 and the diffusion of metal elements between the surface of metal nanoparticles 103 and melted solder alloy 102. Flux 105 is not limited as long as it contains a component for removing an oxide film present on the surface of solder alloy 102 and a solvent having a boiling point higher than the melting point of solder alloy 102 for preventing re-oxidation during the bonding process.

### Examples

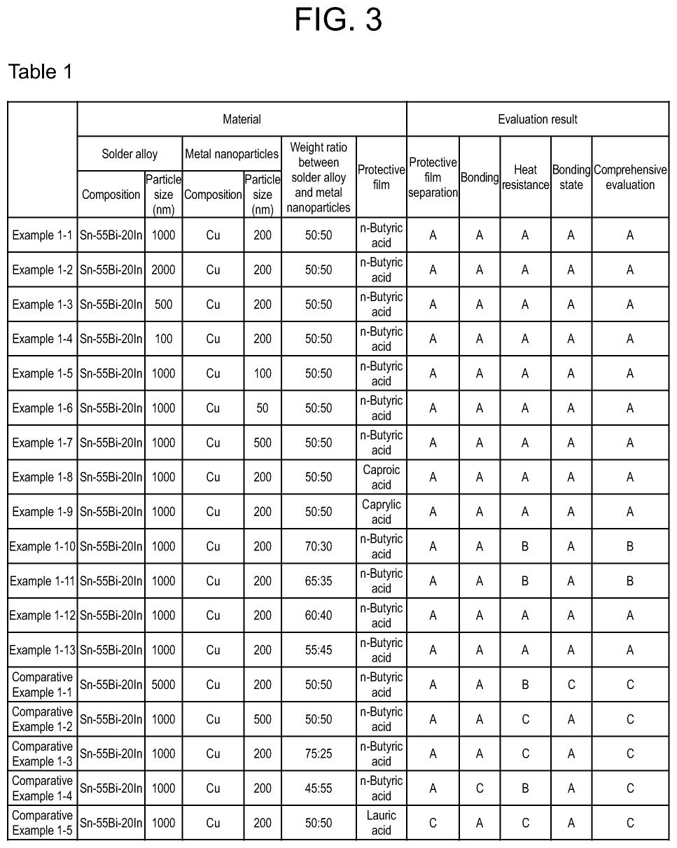

To confirm the effect of the present first exemplary embodiment, bonding material 101 in which the particle sizes and mixing ratio of solder alloy 102 and metal nanoparticles 103 and type of protective film 104 are changed is produced as Examples 1-1 to 1-13 and Comparative Examples 1-1 to 1-5. The components contained in bonding material 101 and the weight ratio thereof, the particle sizes of solder alloy 102 and metal nanoparticles 103, and the evaluation results in Examples 1-1 to 1-8 and Comparative Examples 1-1 to 1-12 are shown in Table 1 of FIG. 3. The particle sizes of solder alloy 102 and metal nanoparticles 103 shown in Table 1 are all the median diameter D50.

### <Bonding Material 101>

As solder alloy 102 in the present first exemplary embodiment, Sn-55wt. % Bi-20wt. % In is evaluated. Cu nanoparticles are evaluated as metal nanoparticles.

Bonding material 101 is produced as follows.
(1) First, metal nanoparticles 103 are weighed so as to have a desired amount, and their surfaces are covered with protective film 104.
(2) Next, solder alloy 102 is weighed, added, mechanically kneaded, and uniformly mixed.
(3) Thereafter, flux 105 is weighed, added, and kneaded by a two-screw planetary kneader to obtain bonding material 101.

### <Bonding Process>

Bonding structure 106 is produced to confirm the effect of the present first exemplary embodiment. The bonding process is as follows.

First, bonding is performed using produced bonding material 101.
(a) Bonding material 101 is supplied onto a Cu plate using a metal mask having a thickness of 100 μm and an opening of 1 mm×1 mm.
(b) A Si element is mounted on the supplied bonding material 101. An electrode of the Si element bonded with bonding material 101 is formed by plating of Ti/Ni/Au from the Si side.
(c) A load of 1 MPa is applied from above the mounted Si element, and heating is performed at 100° C. for 10 minutes in an N₂ atmosphere to produce bonding structure 106 in which the electrode of the Si element and the Cu plate are bonded with bonding material 101.

### <Protective Film Separation Evaluation>

The results of the evaluation for confirming the effect of the present first exemplary embodiment are also shown in Table 1 of FIG. 3.

Metal nanoparticles 103 whose surfaces are covered with protective film 104 are evaluated by simultaneous differential thermal and thermogravimetric measurement (TG/DTA). In Table 1, the nanoparticles are determined as “A” when a weight loss accompanied by reaction heat is observed at TG/DTA at a temperature of more than or equal to melting point (solidus temperature: 78° C.) of the solder alloy and less than or equal to 100° C., which is regarded as having separation of protective film 104, and the nanoparticles are determined as “C” when no weight loss accompanied by reaction heat is observed.

### <Bonding Evaluation>

After performing a series of bonding processes, whether the Cu plate and the electrode of the Si element are bonded is checked. In Table 1, it is determined as “A” when bonded, and “C” when not bonded.

### <Heat Resistance Evaluation>

Next, heat resistance after bonding is evaluated. Bonding material 101 is taken out from the produced bonding structure 106, and evaluation of TG/DTA is performed. In TG/DTA, the heat resistance is determined as “B” when there is no endothermic behavior at a temperature lower than the melting point (232° C.) of Sn, in particular, it is determined as “A” when there is no endothermic behavior at a temperature lower than the melting point (271° C.) of Bi, and it is determined as “C” when an endothermic behavior is observed at a temperature lower than the melting point of Sn.

### <Bonding State Evaluation>

Further, the bonding state of bonding structure 106 is evaluated through section observation. The produced bonding structure 106 is observed with an electron microscope (SEM), and when no abnormality is observed in formed intermetallic compound 112, the structure is determined as “A”, and when a significant void exists inside intermetallic compound 112, the structure is determined as “C”.

### <Comprehensive Evaluation>

When there is no “C” in all the items of the above evaluation, it is determined as “B”, and in such a case, when, in particular, heat resistance is “A”, it is determined as “A”, and when there is at least one item of “C”, it is determined as “C”.

As illustrated in Table 1 of FIG. 3, Examples 1-1 to 1-9, 1-12, and 1-13 among Examples 1-1 to 1-13 were determined as “A” for all of the protective film separation evaluation, the bonding evaluation, the heat resistance evaluation, and the bonding state evaluation. Examples 1-10 and 1-11 were determined as “A” in the protective film separation evaluation, the bonding evaluation, and the bonding state evaluation, and determined as “B” for the heat resistance evaluation. All of Examples 1-1 to 1-13 exceed the evaluation standard.

In these Examples, the particle size of solder alloy 102 is 100 nm to 2000 nm in comparison between Examples 1-1 to 1-4. The particle size of metal nanoparticles 103 is 50 nm to 500 nm in comparison between Examples 1-1, 1-5, and 1-6. Protective film 104 in Examples 1-1 to 1-13 is a linear carboxylic acid in which n-butyric acid, caproic acid, and caprylic acid have 4 to 8 carbon atoms. Further, the heat resistance is “A” when the weight ratio of the metal nanoparticles is 40 wt. % to 50 wt. %, and the heat resistance is “B” when the weight ratio of the metal nanoparticles is 30 wt. % to 35 wt. % in comparison between Examples 1-1 and 1-10 to 1-13.

On the other hand, in Comparative Example 1-1, as a result of sectional observation after bonding, a void of several um was observed in the formed intermetallic compound, and was determined as “C” for the bonding state evaluation. This phenomenon has not completely elucidated, but it is considered as follows. It is considered that since the particle size of solder alloy 102 used in Comparative Example 1-1 is 5000 nm, which is larger than the particle size of metal nanoparticles 103, an intermetallic compound is generated at the surface layer of solder alloy 102, and in solder alloy 102, a reaction of generating an intermetallic compound does not occur instantaneously, but an intermetallic compound is generated by element diffusion via the intermetallic compound at the surface layer.

Comparative Examples 1-2 and 1-3 were determined as “C” in the heat resistance evaluation. This is because solder alloy 102 remains in any case. In Comparative Example 1-2, it is considered that this is because the particle size of metal nanoparticles 103 is large, and the inside of metal nanoparticles 103 is not sufficiently reacted after bonding. In Comparative Example 1-3, it is considered that this is because the weight ratio of metal nanoparticles 103 is as small as 25 wt. %.

When the change in solidus temperature depending on the weight ratio of Sn-55 wt. % Bi-20 wt.% In and Cu is analyzed in a calculation equilibrium state diagram (Thermo-calc), it can be confirmed that the temperature is less than or equal to 100° C. when the weight ratio of Cu as metal nanoparticles 103 is less than or equal to 25 wt. %, the temperature is around 232° C. which is the melting point of Sn when the weight ratio is 30 wt. % to 37.5 wt. %, and the temperature is around 271° C. which is the melting point of Bi when the weight ratio is more than or equal to 40 wt. %, and they are consistent with the above results.

On the other hand, Comparative Example 1-4 was determined as “C” in the bonding evaluation. This is considered to be because the weight ratio of metal nanoparticles 103 is as large as 55 wt. %, solder alloy 102 does not sufficiently wet and spread when melting, and the network formation of the intermetallic compound is insufficient.

In Comparative Example 1-5, lauric acid having 12 carbon atoms was used for the protective film, and weight loss accompanied by reaction heat was not observed at a temperature of more than or equal to the melting point of the solder alloy and less than or equal to 100° C. The heat resistance was also “C”. This is considered to be because the separation of the protective film from the surfaces of the metal nanoparticles 103 is not smoothly performed in the bonding process, and the rate of the formation of the intermetallic compound on the surfaces of the metal nanoparticles 103 is low, and thus the formation of the intermetallic compound does not sufficiently proceed in the bonding process at 100° C. for 10 minutes.

From the results of the present first exemplary embodiment, the following is confirmed.

To exhibit the effect of the present disclosure, first, the particle size of solder alloy 102 needs to be 100 nm to 2000 nm.

Next, the particle size of metal nanoparticles 103 needs to be 50 nm to 500 nm.

Further, it is necessary that the weight ratio of metal nanoparticles is 30 wt. % to 50 wt. %, and it is particularly desirable that the weight ratio is 40 wt. % to 50 wt. %. This means that the weight ratio between solder alloy 102 and metal nanoparticles 103 is a ratio at which all Sn and In contained in the solder alloy become intermetallic compounds with metal nanoparticles 103 in an equilibrium state diagram.

Then, it is necessary that protective film 104 separates at a temperature higher than the melting point of solder alloy 102 and lower than 100° C.

In bonding material 101 satisfying these conditions, it is possible to provide a bonding material capable of forming a bonding portion having high heat resistance at a low temperature of 100° C. for a short time of 10 minutes.

### Second Exemplary Embodiment

As a second exemplary embodiment, the influence of the metal composition of solder alloy 102 is evaluated.

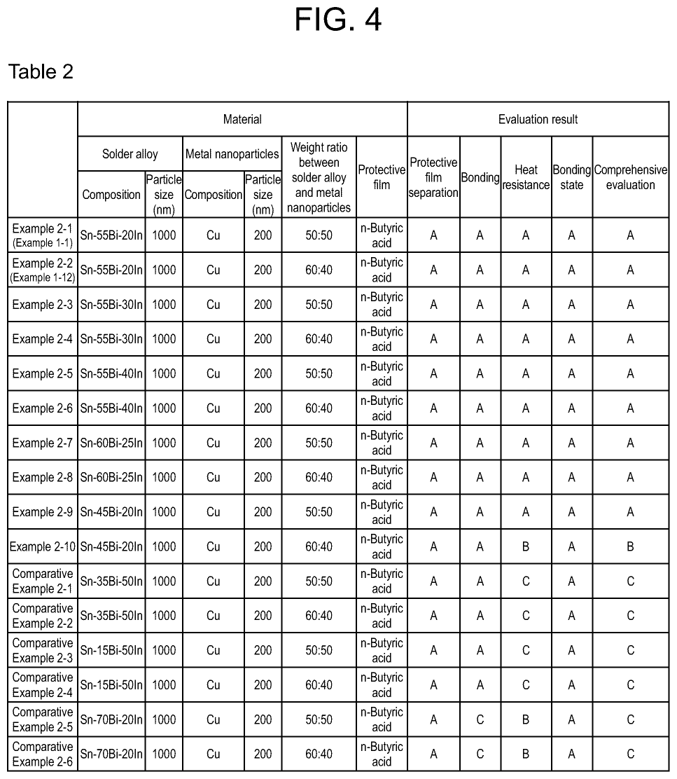

To confirm the effect of the present second exemplary embodiment, bonding material 101 in which the metal composition of solder alloy 102 and the mixing proportion of solder alloy 102 and metal nanoparticles 103 are changed is produced as Examples 2-1 to 2-10 and Comparative Examples 2-1 to 2-6. The conditions and evaluation results of bonding material 101 in Examples 2-1 to 2-10 and Comparative Examples 2-1 to 2-6 are shown in Table 2 of FIG. 4.

A method for producing bonding material 101, a bonding process, and an evaluation method are the same as those in the first exemplary embodiment and the second exemplary embodiment.

From Table 2 in FIG. 4, focusing on the metal composition of solder alloy 102, Examples 2-1 to 2-8 in which the Bi ratio is 55 wt. % to 60 wt. % were determined as “A” in all of the protective film separation evaluation, the bonding evaluation, the bonding state evaluation, and the heat resistance evaluation. Example 2-9 in which the Bi ratio was 45 wt. % and the weight ratio of the metal nanoparticles was 50 wt. % was determined as “A” in all of the protective film separation evaluation, the bonding evaluation, the heat resistance evaluation, and the bonding state. Example 2-10 in which the Bi ratio was 45 wt. % and the weight ratio of the metal nanoparticles was 40 wt. % was determined as “A” in the protective film separation evaluation, the bonding evaluation, and the bonding state, and determined as “B” in the heat resistance evaluation. All of Examples 2-1 to 2-10 exceed the evaluation standard.

On the other hand, Comparative Examples 2-1 to 2-4 in which the Bi ratios are as small as 15 wt. % and 35 wt. % determined as “C” in the heat resistance despite the low melting point as compared with solder alloy 102 of Examples 2-1 to 2-10. This is considered to be because the proportion of Sn and In, which are components forming an intermetallic compound with Cu of metal nanoparticles 103 in solder alloy 102, is large, thus a large amount of Cu is required to completely form an intermetallic compound, and the metal nanoparticles are insufficient.

Comparative Examples 2-5 and 2-6 in which the Bi ratio is as high as 70 wt. % were determined as “C” for the bonding. This is considered to be because the liquidus temperature increases as the Bi ratio increases, and thus the bonding material does not sufficiently melt at 100° C.

From the result of the present second exemplary embodiment, the following is confirmed.

The composition of solder alloy 102 needs to have a Bi ratio of 45 wt. % to 60 wt. %, and the ratio is particularly preferably 55 wt. % to 60 wt. %. In particular, Sn-55 wt. % Bi-20 wt. % In, which has a wide range of allowable weight ratios of metal nanoparticles and has a low content proportion of In of high cost, is most preferable.

In bonding material 101 satisfying these conditions, it is possible to provide a bonding material capable of forming a bonding portion having high bonding strength.

### <Preferred Condition of the Present Invention>

From the results of the present first and second exemplary embodiments, as preferable conditions for exhibiting the effect of the bonding material of the present disclosure, bonding material 101 may contain solder alloy 102 having a median diameter D50 of 100 nm to 2000 nm, made from Sn, Bi, In, and other inevitable components, and having a melting point of less than or equal to 100° C., metal nanoparticles 103 that are Cu nanoparticles capable of forming an intermetallic compound with Sn and In contained in solder alloy 102, metal nanoparticles 103 having a median diameter D50 of 50 nm to 500 nm, and flux 105. Metal nanoparticles 103 may have protective film 104 on their surfaces, protective film 104 separating at a temperature higher than the melting point of solder alloy 102 and lower than 100° C. The weight ratio between solder alloy 102 and metal nanoparticles 103 is preferably a ratio at which all Sn and In contained in solder alloy 102 become intermetallic compounds with metal nanoparticles 103 in an equilibrium state diagram.

More preferably, the composition of solder alloy 102 is preferably Sn-55 wt. % Bi-20 wt. % In.

Still more preferably, the weight ratio of metal nanoparticles 103 to the total weight of solder alloy 102 and metal nanoparticles 103 is preferably 30 wt. % to 50 wt. %, still more preferably 37.5 wt. % to 50 wt. %, and most preferably 40 wt. % to 50 wt. %.

Protective film 104 is preferably a linear carboxylic acid having 4 to 8 carbon atoms.

A bonding structure is a bonding structure including an electronic component having a first electrode, a circuit board having a second electrode, and a bonding layer. In the bonding structure, the first electrode and the second electrode are bonded by the bonding layer, the bonding layer is connected between the first electrode and the second electrode by an intermetallic compound made from two or more elements of Cu, Sn, and In, and a Bi-containing portion is included in an island shape in a base of the intermetallic compound.

The ratio of Bi may be 40 vol. % to 45 vol. %.

Although Ti/Ni/Au is used as the electrode of the Si element used for the evaluation in the present exemplary embodiments, the present disclosure is not limited to this configuration. The effect of the present disclosure can be exhibited as long as the electrode can be bonded with solder alloy 102.

In addition, in the present exemplary embodiments, a Cu plate is used for bonding, but the present disclosure is not limited to this configuration. The effect of the present disclosure can be exhibited as long as the electrode can be bonded with solder alloy 102 and the material can withstand 100° C., which is the temperature of the bonding process.

The present disclosure includes an appropriate combination of any exemplary embodiment or example among the various above-described exemplary embodiments or examples, and effects of each of the exemplary embodiments or examples can be achieved.

### INDUSTRIAL APPLICABILITY

According to the bonding material and the bonding structure of the present disclosure, it is possible to provide a bonding material and a bonding structure capable of exhibiting high heat resistance with heating at a low temperature for a short time, and it is possible to use a resin having low heat resistance as a base material in printable electronics and the like.

### REFERENCE MARKS IN THE DRAWINGS

101: bonding material
102: solder alloy
103: metal nanoparticles
104: protective film
105: flux
106: bonding structure
107: first electrode
108: electronic component
109: second electrode
110: circuit board
111: bonding layer
112: intermetallic compound
113: Bi-containing portion

1. A bonding material comprising:
a solder alloy having a median diameter D50 of 100 nm to 2000 nm, made from Sn, Bi, In, and other unavoidable components, and having a melting point of less than or equal to 100° C.;
metal nanoparticles that are Cu nanoparticles having a median diameter D50 of 50 nm to 500 nm; and
a flux component, wherein
the metal nanoparticles include a protective film on a surface of the metal nanoparticles, the protective film separating at a temperature higher than a melting point of the solder alloy and lower than 100° C., and
a weight ratio between the solder alloy and the metal nanoparticles is a ratio at which all Sn and In contained in the solder alloy become intermetallic compounds with the metal nanoparticles in an equilibrium state diagram.

2. The bonding material according to claim 1, wherein a composition of the solder alloy is Sn-55 wt. % Bi-20 wt. % In.

3. The bonding material according to claim 1, wherein a weight ratio of the metal nanoparticles to a total weight of the solder alloy and the metal nanoparticles is 30 wt. % to 50 wt. %.

4. The bonding material according to claim 1, wherein a weight ratio of the metal nanoparticles to a total weight of the solder alloy and the metal nanoparticles is 37.5 wt. % to 50 wt. %.

5. The bonding material according to claim 1, wherein a weight ratio of the metal nanoparticles to a total weight of the solder alloy and the metal nanoparticles is 40 wt. % to 50 wt. %.

6. The bonding material according to claim 1, wherein the protective film is a linear carboxylic acid having 4 to 8 carbon atoms.

7. A bonding structure comprising:
an electronic component including a first electrode;
a circuit board including a second electrode; and
a bonding layer between the first electrode and the second electrode, wherein
the first electrode and the second electrode are bonded by the bonding layer,
the bonding layer is connected between the first electrode and the second electrode by an intermetallic compound of Cu, Sn, and In, and
a Bi-containing portion is included in an island shape in a base of the intermetallic compound made from two or more elements of Cu, Sn, and In.

8. The bonding structure according to claim 7, wherein the Bi-containing portion is included in 40 vol. % to 45 vol. %.
